(19) United States
(12) Patent Application Publication
(10) Pub. No.: US 2011/0274826 A1
(43) Pub. Date: Nov. 10, 2011

(54) METHOD OF MANUFACTURING POLARIZING MEMBER

(75) Inventor: Noriaki TAGUCHI, Shinjuku-ku (JP)

(73) Assignee: HOYA CORPORATION, Tokyo (JP)

(21) Appl. No.: 12/977,880

(22) Filed: Dec. 23, 2010

(30) Foreign Application Priority Data
Dec. 24, 2009 (JP) 2009-291894

(51) Int. Cl. C23C 16/52

(52) U.S. Cl. 427/8

(57) ABSTRACT

An embodiment of the present invention relates to a method of manufacturing a polarizing member comprising forming a polarizing film by coating a dichroic dye-containing solution on an orienting layer, preparing an epoxy group-containing silane coupling agent solution by adding an epoxy group-containing silane coupling agent to an aqueous solvent, coating the epoxy group-containing silane coupling agent solution thus prepared on the polarizing film and then conducting thermoprocessing, and determining the time elapsing between the preparation of the epoxy group-containing silane coupling agent solution and the coating thereof based on change in an average molecular weight of the silane coupling agent in the epoxy group-containing silane coupling agent solution.

### CROSS-REFERENCE TO RELATED APPLICATIONS

This application claims the benefit of priority under 35 USC 119 to Japanese Patent Application No. 2009-291894, filed on Dec. 24, 2009, which is expressly incorporated herein by reference in its entirety.

### BACKGROUND OF THE INVENTION

1. Field of the Invention

The present invention relates to a method of manufacturing a polarizing member, and particularly, to a method of manufacturing a polarizing member in which cloud (haze) is suppressed.

2. Discussion of the Background

Polarizing lenses are used as anti-glare glasses in specific industries such as the welding and medical treatments, as well as in various sports such as skiing. Generally, the polarizing property of a dichroic dye is used to combat glare. The polarizing property of dichroic dyes is widely utilized in optical applications such as display devices, light-transmitting devices, and automobile and window glass.

The polarizing property of a dichroic dye is principally achieved by uniaxially orienting the dichroic dye. To uniaxially orient a dichroic dye, the method of impregnating a polyvinyl alcohol (PVA) with a dichroic dye and uniaxially extending the film, and the method of coating a coating liquid containing a dichroic dye on an orienting layer are generally employed. Orienting layers have been proposed in the form of an inorganic intermediate layer of silica (SiO₂) vapor deposited film (see Reference 1 (WO2006/081006) and family members US2006/146234A1, US2010/028532A1, and U.S. Pat. No. 7,625,626, which are expressly incorporated herein by reference in their entirety), a silicon-containing sol-gel film (see Reference 2 (Japanese Unexamined Patent Publication (KOKAI) No. 2009-237361) and English language family member EP2 259 101A1, which are expressly incorporated herein by reference in their entirety), and the like.

### SUMMARY OF THE INVENTION

The forming of a protective layer with silane coupling agents after providing a polarizing film on the orienting layer, specifically, the forming of a protective layer by sequentially coating and heat curing 3-aminopropyltriethoxysilane (an amino group-containing coupling agent) and 3-glycidoxypropyltrimethoxysilane (an epoxy group-containing coupling agent) is disclosed in Examples of above Reference 1. The silane coupling agent contained in the protective layer is thought to play the role of penetrating the polarizing film and locking in the oriented state of the dichroic dye. However, as a result of investigation by the present inventor, it has become clear that cloud (haze) sometimes develops in the polarizing member on which the protective layer is formed.

An aspect of the present invention provides for a high-quality polarizing member in which haze is suppressed.

The present inventor conducted extensive research into achieving the above-stated object, resulting in the following discoveries.

Reference 2 states that cracks sometimes develop in the orienting layer due to the difference in thermal expansion of the orienting layer and the substrate, causing haze in the polarizing member having an orienting layer comprised of an inorganic substance. When the present inventor observed those polarizing members that developed haze, it became clear that the development of cracks in the polarizing film sometimes caused haze. Further, pronounced cracking of the polarizing film was determined to occur when a protective layer was formed using an epoxy group-containing silane coupling agent as described in Examples of Patent Reference 1. Accordingly, one conceivable means of reducing cracking was to form the protective layer without using an epoxy group-containing silane coupling agent. However, since an epoxy group-containing silane coupling agent is useful for immobilizing the dichroic dye, the present inventor conducted further research into discovering a means of reducing cracking in the polarizing film when employing an epoxy group-containing silane coupling agent as a component of the protective layer. As a result, they discovered that:
(i) when an epoxy group-containing silane coupling agent was added to an aqueous solvent to prepare a protective layer-forming solution, the average molecular weight of the silane coupling agent changed over time; and
(ii) for reasons which remain unclear, it was possible to suppress the formation of cracks in the polarizing film by determining when to use the protective layer-forming solution based on this change in molecular weight over time. The fact that cracks are generated in the polarizing film due to the components forming the protective layer employed to immobilize the dichroic dye was previously unknown. The identification of a correlation between the generation of cracks in the polarizing film and changes in the average molecular weight of the epoxy group-containing silane coupling agent was discovered for the first time ever by the present inventor.

The present invention was devised on the basis of the above discovery.

An aspect of the present invention relates to:
a method of manufacturing a polarizing member comprising:
forming a polarizing film by coating a dichroic dye-containing solution on an orienting layer,
preparing an epoxy group-containing silane coupling agent solution by adding an epoxy group-containing silane coupling agent to an aqueous solvent,
coating the epoxy group-containing silane coupling agent solution thus prepared on the polarizing film and then conducting thermoprocessing, and
determining the time elapsing between the preparation of the epoxy group-containing silane coupling agent solution and the coating thereof based on change in an average molecular weight of the silane coupling agent in the epoxy group-containing silane coupling agent solution.

The above epoxy group-containing silane coupling agent solution may have a property in that the average molecular weight undergoes a temporary drop, after which it begins to increase. In that case, the time elapsing between the preparation and the coating may be set within a period from when the solution is prepared to when a given period is elapsed following the start of the increase in the average molecular weight.

The above method of manufacturing a polarizing member may further comprises forming a functional film on the polarizing film that has been subjected to the thermoprocessing.

The above method of manufacturing a polarizing member may comprise, prior to coating the epoxy group-containing silane coupling agent solution, coating an amino group-containing silane coupling agent solution on the polarizing film and then conducting thermoprocessing.

The dichroic dye may be water-soluble. In that case, the above method of manufacturing a polarizing member may comprise subjecting the polarizing film formed to water-insolubilizing treatment of the dichroic dye.

The above orienting layer may comprise an oxide of silicon.

The above polarizing member may be a polarizing lens.

According to the present invention, a high-quality polarizing member in which haze due to cracking of the polarizing film is suppressed can be provided.

### BRIEF DESCRIPTION OF THE DRAWINGS

FIG. 1 is a pattern graph showing the change over time in the average molecular weight of an epoxy group-containing silane coupling agent.

FIG. 2 is a graph showing the change over time in the average molecular weight of a γ-glycidoxypropyltrimethoxysilane aqueous solution.

FIG. 3 is a sectional photograph by scanning electron microscope (SEM) of a polarizing lens fabricated using a γ-glycidoxypropyltrimethoxysilane aqueous solution two weeks after preparation.

FIG. 4 is a graph showing the relation between the haze value of a polarizing lens and the number of days that had elapsed following preparation of the γ-glycidoxypropyltrimethoxysilane aqueous solution at the time of use.

### DETAILED DESCRIPTION OF THE EMBODIMENTS

An aspect of the present invention relates to:
a method of manufacturing a polarizing member comprising:
forming a polarizing film by coating a dichroic dye-containing solution on an orienting layer (referred to as “step 1”, hereinafter),
preparing an epoxy group-containing silane coupling agent solution by adding an epoxy group-containing silane coupling agent to an aqueous solvent (referred to as “step 2”, hereinafter), and
coating the epoxy group-containing silane coupling agent solution thus prepared on the polarizing film and then conducting thermoprocessing (referred to as “step 3”, hereinafter). In the manufacturing method of the present invention, the time elapsing between the preparation of the epoxy group-containing silane coupling agent solution and the coating thereof is determined based on change in an average molecular weight of the silane coupling agent in the epoxy group-containing silane coupling agent solution. As set forth above, this permits reduction or suppression of cracking in the polarizing film, thereby making it possible to provide a high-quality polarizing member in which haze is suppressed.

The manufacturing method of the present invention will be described below in greater detail.

### Step 1

In step 1, a polarizing film is formed by coating a dichroic dye-containing solution on an orienting layer. Uniaxially orienting the dichroic dye in the present step can develop the good polarizing property.

The orienting layer is normally provided directly on the substrate or indirectly thereupon over some other layer. The substrate is not specifically limited; examples are plastics and inorganic glasses. Examples of plastics are methyl methacrylate homopolymers; copolymers of methyl methacrylate and one or more other monomers; diethylene glycol bisallylcarbonate homopolymers; copolymers of diethylene glycol bisallylcarbonate and one or more other monomers; sulfur-containing copolymers; halogen copolymers; polycarbonate; polystyrene; polyvinyl chloride; unsaturated polyester; polyethylene terephthalate; polyurethane; polythiourethane; polymers made from materials including epithio group-containing compounds; homopolymers of sulfide bond-containing monomers; copolymers of a sulfide and one or more other monomers; copolymers of a polysulfide and one or more other monomers; and copolymers of a polydisulfide and one or more other monomers. The surface configuration of the substrate on which the orienting layer is formed is not specifically limited. It can be of any shape, including planar, convex, and concave shapes. The thickness of the substrate is determined based on the type of polarizing member and is not specifically limited. For example, when manufacturing a polarizing lens as a polarizing member, the substrate is normally about 0.5 to 30 mm in thickness.

A hardcoat layer is an example of a layer that can be formed between the substrate and the orienting layer. The hardcoat layer is not specifically limited. A coating in which a microparticulate metal oxide is added to an organic silicon compound is suitable. Instead of an organic silicon compound, an acrylic compound can be employed. Further, a known UV-curable resin or EB-curable resin, such as an acrylate monomer or oligomer, can be employed as a coating composition for forming a hard coat. For the details of the hardcoat layer, reference can be made to paragraphs [0071] to [0074] in Japanese Unexamined Patent Publication (KOKAI) No. 2007-77327 and paragraph [0027] in Japanese Unexamined Patent Publication (KOKAI) No. 2009-237361, for example. The contents of the above publications are expressly incorporated herein by reference in their entirety. The thickness of the hardcoat layer is, for example, about 0.5 to 10 μm. Lens substrates with hardcoats are commercially available; an orienting layer can be formed on such a lens substrate in the present invention.

The thickness of the orienting layer is normally about 0.02 to 5 μm, desirably about 0.05 to 0.5 μm. The orienting layer can be formed by depositing a film-forming material by a known film-forming method such as vapor deposition or sputtering, or formed by a known coating method such as dipping or spin coating. Examples of suitable film-forming materials are silicon oxides, metal oxides, and complexes and compounds thereof. The use of the oxide of a material selected from among Si, Al, Zr, Ti, Ge, Sn, In, Zn, Sb, Ta, Nb, V, and Y, as well as complexes or compounds of these materials, is preferred. Of these, from the perspective of the ease of imparting functions to the orienting layer, oxides of silicon such as SiO and SiO₂ are desirable. Of these, from the perspective of reactivity with the silane coupling agent described further below, SiO₂ is preferred.

On the other hand, an example of the orienting layer that is formed by the above-described coating method is a sol-gel film containing an inorganic oxide sol. Examples of suitable coating liquids for forming the sol-gel film are coating liquids containing an inorganic oxide sol and at least one from among alkoxysilanes and hexaalkoxydisiloxanes. From the perspective of the ease of imparting functions to the orienting film, the above alkoxysilane is desirably the alkoxysilane denoted by general formula (1) in Japanese Unexamined Patent Publication (KOKAI) No. 2009-237361 and the above hexaalkoxydisiloxane is desirably the hexaalkoxydisiloxane denoted by general formula (2) in Japanese Unexamined Patent Publication (KOKAI) No. 2009-237361. The coating liquid can contain one of an alkoxysilane and a hexaalkoxydisiloxane, or both. Further, as needed, the functional group-containing alkoxysilane denoted by general formula (3) in Japanese Unexamined Patent Publication (KOKAI) No. 2009-237361 can be incorporated. For details regarding the coating liquid and film-forming method (coating method), reference can be made to paragraphs [0011] to [0023] and [0029] to [0031] of Japanese Unexamined Patent Publication (KOKAI) No. 2009-237361 and Examples described in the same publication.

Next, to uniaxially orient the dichroic dye in the coating liquid that is coated on the orienting layer, grooves are normally formed on the orienting layer that has been formed. When the dichroic dye-containing coating liquid is coated on the surface of an orienting layer in which grooves have been formed, the dichroic dye orients itself either along the grooves or perpendicular to them. Thus, the dichroic dye is uniaxially oriented, permitting development of its good polarizing property. For example, the grooves can be formed by the rubbing step that is conducted to orient liquid crystal molecules. A rubbing step is a step in which a surface being polished is rubbed in a single direction with fabric or the like. For the details thereof, reference can be made to U.S. Pat. Nos. 2,400,877 and 4,865,668, for example. The contents of the above publications are expressly incorporated herein by reference in their entirety. Grooves can also be formed on the orienting layer by the polishing treatment described in paragraphs [0033] and [0034] in Japanese Unexamined Patent Publication (KOKAI) No. 2009-237361. It suffices to set the depth and pitch of the grooves that are formed in a manner permitting uniaxial orientation of the dichroic dye.

The method of forming the polarizing film (dichroic dye film) on the orienting layer will be described next.

The term “dichroic” refers to the property whereby the color of transmitted light varies with the direction of propagation due to anisotropy of selective absorption of light by a medium. A dichroic dye has the property of strong absorption of polarized light in a specific orientation of the dye molecules and weak absorption in a direction orthogonal thereto. Some dichroic dyes are known to exhibit liquid crystal states at certain concentrations and in certain temperature ranges when water is employed as a solvent. Such liquid crystal states are called as lyotropic liquid crystals. Stronger dichroism can be achieved by using the liquid-crystal states of dichroic dyes to orient the dye molecules in a specific direction. Coating a coating liquid containing a dichroic dye on an orienting layer in which grooves have been formed makes it possible to uniaxially orient the dichroic dye, permitting the formation of a polarizing layer with good polarizing property.

The dichroic dye employed in the present invention is not specifically limited. Examples are various dichroic dyes that are commonly employed in polarizing members. Specific examples are azo dyes, anthraquinone dyes, merocyanine dyes, styryl dyes, azomethine dyes, quinone dyes, quinophthalone dyes, perylene dyes, indigo dyes, tetrazine dyes, stilbene dyes, and benzidine dyes. The dyes described in U.S. Pat. No. 2,400,877, Published Japanese Translation (TOKUHYO) No. 2002-527786 of a PCT International Application, and the like may also be employed. The contents of the above publications are expressly incorporated herein by reference in their entirety.

The dichroic dye-containing coating liquid can be a solution or a suspension. Many dichroic dyes are water soluble. Thus, the coating liquid is normally a an aqueous solution or an aqueous suspension with water as solvent. The content of dichroic dye in the coating liquid can be, for example, about 1 to 50 mass percent, but is not limited to this range so long as the desired polarizing property is achieved.

The coating liquid can contain other components in addition to the dichroic dye. An example of another component is a dye other than a dichroic dye. Compounding such dyes makes it possible to manufacture a polarizing member of desired color. From the perspective of further enhancing coating properties and the like, additives such as rheology-modifying agents, adhesion-enhancing agents, plasticizers, and leveling agents can be compounded.

The method of coating the coating liquid is not specifically limited; examples are the above known methods such as dipping and spin coating. The thickness of the polarizing film is not specifically limited, but is normally about 0.05 to 5 μm. The silane coupling agent described further below is normally used to impregnate the polarizing film and is substantially contained in the polarizing film.

When employing a water-soluble dye as the dichroic dye, a water-insolubilizing treatment is desirably conducted after coating and drying the coating liquid to enhance the stability of the film. The water-insolubilizing treatment can be conducted by, for example, ion exchanging the terminal hydroxyl group of the dye molecule or by creating a state of chelation between the dye and a metal salt. To this end, the method of immersing the polarizing film that has been formed in a metal salt aqueous solution is desirably employed. The metal salt that is employed is not specifically limited; examples are AlCl₃, BaCl₂, CdCl₂, ZnCl₂, FeCl₂, and SnCl₃. After the water-insolubilizing treatment, the surface of the polarizing film can be dried again.

In the manufacturing method of the present invention, the polarizing film that has been formed in step 1 is coated with an epoxy group-containing silane coupling agent solution and then subjected to thermoprocessing (step 3). Thus, the orientation state of the dichroic dye can be immobilized in the polarizing film and the film strength and stability can be enhanced. However, as set forth above, research conducted by the present inventor has clearly revealed that cloud (haze) due to cracking of the polarizing film is sometimes produced in polarizing members prepared using epoxy group-containing silane coupling agents. Accordingly, in the present invention, the time at which the coupling agent solution is employed in step 3 is determined based on the change in the average molecular weight of the coupling agent solution over time. Step 2 will be described below and then how the time of use is determined will be described.

### Step 2

In this step, the epoxy group-containing silane coupling agent is added to the aqueous solvent to prepare an epoxy group-containing silane coupling agent solution. The silane coupling agent generally has a structure denoted by R—Si(OR′)₃ (wherein the multiple instances of R′ may be identical or different). The term “epoxy group-containing silane coupling agent” refers to a silane coupling agent that contains an epoxy group as the functional group denoted by R. The epoxy group is normally bonded to the Si through a divalent linking group. Examples of divalent linking groups are the linking groups contained in the specific example compounds set forth further below.

Additionally, the functional group denoted by R′ is a common alkyl group that is hydrolyzed in the aqueous solvent, producing silanol (Si—OH). The alkyl group denoted by R′ comprises for example 1 to 10, desirably 1 to 3, carbon atoms.

Specific examples of the epoxy group-containing silane coupling agent are: γ-glycidoxypropyltrimethoxysilane (γ-GPS), γ-glycidoxypropylmethyldiethoxysilane, and other glycidoxy group-containing trialkoxysilanes; and β-(3,4-epoxycyclohexyl)ethyltrimethoxysilane, β-(3,4-epoxycyclohexyl)ethyltriethoxysilane, β-(3,4-epoxycylohexyl)ethyltripropoxysilane, β-(3,4-epoxycyclohexyl)-ethyltributoxysilane, γ-(3,4-epoxycyclohexyl)propyltrimethoxysilane, γ-(3,4-epoxycyclohexyl)propyltriethoxysilane, δ-(3,4-epoxycyclohexyl)butyltrimethoxysilane, δ-(3,4-epoxycyclohexyl)butyltriethoxysilane, and other epoxyalkylalkoxysilanes.

Investigation by the present inventor has revealed that when the above epoxy group-containing silane coupling agent is added to an aqueous solvent to prepare a silane coupling agent solution, a change in the average molecular weight is observed within a relatively short period following preparation (for example, within about two weeks). This phenomenon was not seen in the amino group-containing silane coupling agents set forth further below. That is because epoxy group-containing silane coupling agents are highly reactive among silane coupling agents. As a result, the generation of silanol groups by hydrolysis over a relatively short period during solution storage and the formation (generation of silane oligomers) of siloxane bonds (Si—O—Si) by the condensation of silanol groups are presumed as tending to cause a change in the average molecular weight. Solutions in which large numbers of silane oligomers are produced cannot adequately penetrate when coated on the polarizing film, so most of the epoxy group-containing agent is thought to remain on the polarizing film in the form of a coating. Thermal contraction of the coating due to subsequent thermoprocessing is then presumed by the present inventor to cause cracking in the polarizing film.

The epoxy group-containing silane coupling agent solution is prepared by adding and admixing the epoxy group-containing silane coupling agent to an aqueous solvent, desirably water or a mixed solvent of water and alcohol (methanol, ethanol, or the like). Taking solubility into account, the concentration of the epoxy group-containing silane coupling agent in the solution is desirably about 1 to 15 mass percent, preferably about 1 to 10 mass percent. Known additives can be incorporated as other components in the solution. During preparation of the solution, it is desirable to not conduct heating so as to inhibit sudden changes in the average molecular weight. For the same reason, the solution that is prepared is desirably stored in the condition at or below room temperature.

Determining When to Use the Epoxy Group-Containing Silane Coupling Agent Solution

In the present invention, when to use the epoxy group-containing silane coupling agent solution prepared in step 2, that is, how much time to allow to elapse between the preparation and the coating of the solution, is determined based on the change in the average molecular weight of the silane coupling agent in the epoxy group-containing silane coupling agent solution. In this context, the term “average molecular weight” can be either the weight average molecular weight (also denoted as “Mw” hereinafter) or the number average molecular weight (also denoted as “Mn” hereinafter). In the present invention, the time of use can be determined based on change in either the weight average molecular weight, the number average molecular weight, or both. In the present invention, the average molecular weight is measured as the polystyrene-converted molecular weight by gel permeation chromatography (GPC).

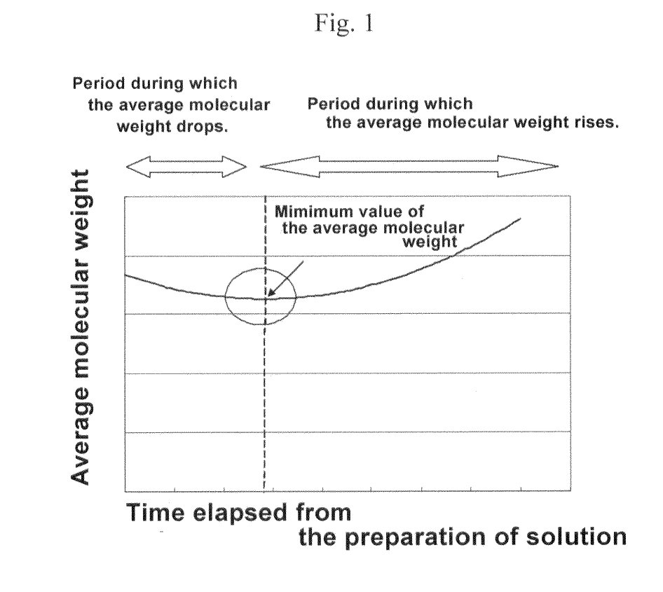

To determine the time of use, a solution (sample solution) containing the same epoxy group-containing silane coupling agent as the solution used in actual production is desirably prepared for testing, and the change in the average molecular weight following preparation of this solution is monitored over time. For example, a suitable quantity of sample for measuring the average molecular weight is collected from the sample solution at regular intervals and the change in the average molecular weight of the sample is measured to obtain information about the change over time in the average molecular weight following the preparation of the solution that is employed in actual production. As shown in FIG. 1, the average molecular weight of the epoxy group-containing silane coupling agent normally undergoes a temporary drop to a minimum value following the preparation of the solution, after which it begins to increase, subsequently tending to rise. That is, following the preparation of the solution, there is a period during which the average molecular weight drops followed by a period during which the average molecular weight rises. During the period in which the average molecular weight drops, the generation of silanol groups by hydrolysis primarily occurs, and during the period in which the molecular weight rises, the formation of siloxane bonds (the generation of silane oligomers) through the condensation of silanol group primarily occurs. As set forth above, cracking of the polymerizing film is presumed to occur due to the generation of large numbers of silane oligomers. Thus, the solution is desirably coated on the polarizing film before large numbers of silane oligomers have generated. Accordingly, when to use the solution (the time elapsing between solution preparation and coating) is desirably set within the period from when the solution is prepared to when a given period has elapsed following the start of the increase in the average molecular weight, and is preferably set to within the period during which the average molecular weight drops. When the time of use is set to within the period during which the average molecular weight is increasing, it is desirably set to within the period during which the average molecular weight that is measured does not exceed the average molecular weight immediately following preparation. To get a grasp of the trend in the change over time of the average molecular weight, the composition of the sample solution does not necessarily have to be identical to the solution used in actual production. However, to be able to exclude the effects of other components, use of a composition containing the same additives is desirable when additives are incorporated, and use of the same aqueous solvent is also desirable. The environment in which the solution is placed in the course of measuring the change over time in the average molecular weight is desirably one that is equivalent to or approximates the atmosphere in which the solution is stored during actual production. For example, when the solution is stored at room temperature during actual production, the solution being measured is also desirably kept at room temperature. When stored in a temperature-controlled environment, the solution being measured is desirably kept in the same temperature-controlled environment. This is done to more accurately determine trends in change over time in the average molecular weight of the epoxy group-containing silane coupling agent during actual production.

### Step 3

In step 3, following the preparation in step 2, the epoxy group-containing silane coupling agent solution is coated on the polarizing film within the period that has been determined by the above-described method and then thermoprocessing is conducted. The solution can be coated by a known means such as dipping, spin coating, or spray coating. The thermoprocessing can be conducted by placing the polarizing member on which the solution has been coated in a heating furnace for a prescribed period. The temperature of the atmosphere in the furnace during heating and the heating period can be determined based on the epoxy group-containing silane coupling agent being employed, and are usually 40 to 200° C. and 30 minutes to 3 hours, respectively.

The epoxy group-containing silane coupling agent can be coated directly on the polarizing film, but is desirably coated after coating and then thermoprocessing an amino group-containing silane coupling agent solution on the polarizing film. This is because amino group-containing silane coupling agents (also referred to as “aminosilanes”, hereinafter) are presumed, due to their molecular structures, to be able to more readily enter between the molecules of the dichroic dye that has been uniaxially oriented by the orienting layer than epoxy group-containing silane coupling agents (also referred to as “epoxysilanes”, hereinafter). This point will be further described. The mechanism by which dichroic dyes are immobilized in an oriented state by silane coupling agents is presumed to be as follows. When a silane coupling agent enters between the molecules of a dichroic dye that has been uniaxially oriented by an orienting layer, the silane coupling agent bonds to the orienting layer by means of silanol groups that are generated by hydrolysis. As a result, the silane coupling agent is immobilized between the molecules of the dichroic dye, making it difficult for the dichroic dye molecules to associate between themselves and maintaining the oriented state of the dichroic dye. When an aminosilane is employed as the coupling agent for bonding to the orienting layer, following thermoprocessing, the amino group is presumed to be immobilized on the orienting layer with the amino group facing upward. As for the reason, the present inventor presumes as follows. When an epoxysilane is coated thereover and thermoprocessing is conducted, the epoxysilane plays the role of a crosslinking agent, increasing the coating strength. Since epoxy groups are highly reactive with amino groups, the epoxy groups form bonds with the amino groups and silanol groups generated by hydrolysis in the epoxysilane condense, forming siloxane bonds.

The above aminosilane consists of the above structure R—Si(OR′)₃ in which the functional group denoted by R contains an amino group. The details of the structure relating to aminosilanes are as set forth above for the epoxy group-containing silane coupling agent with the exception that an amino group is contained in R. Specific examples of aminosilanes are amino group-containing alkoxysilanes such as N-(β-aminoethyl)-γ-aminopropyltrimethoxysilane, N-(β-aminoethyl)-γ-aminopropylmethylmethoxysilane, γ-aminopropylmethyldimethoxysilane, γ-aminopropylmethyldiethoxysilane, γ-aminopropyltrimethoxysilane, γ-aminopropyltriethoxysilane, N-(β(aminoethyl)-γ-aminopropylmethyldimethoxysilane, and N-(β-aminoethyl)-γ-aminopropylmethyldiethoxysilane. Further, details of the method of preparing the aminosilane-containing solution, the coating method, and thermoprocessing are as set forth above for epoxysilane. After coating the silane coupling agent, the coating surface can be rinsed with pure water, deionized water, or the like to remove the excess silane coupling agent that has adhered to the outermost surface.

On the polarizing member that has been subjected to above-described steps 1 to 3, various functional films can be laminated by known film-forming methods as needed over the polarizing film that has been processed with a silane coupling agent. Examples of functional films are a hardcoat film and an antireflective film. A silane coupling agent that is unable to penetrate the polarizing film due to the generation of silane oligomers and remains in the form of a coating on the outermost layer portion is presumed to undergo thermal contraction when subjected to thermoprocessing, producing the above-described cracks in the polarizing film that cause haze. Accordingly, when conducting the thermoprocessing (thermosetting treatment) in the course of forming the functional film on the polarizing film, there is a concern that further progression of thermal contraction due to the thermoprocessing will produce severe cracking. By contrast, in the present invention, by determining when to use the epoxysilane solution as set forth above, it is possible to coat the epoxysilane solution on the polarizing film before a large number of silane oligomers have generated. Thus, even when thermoprocessing is conducted to form a functional film, it is possible to obtain a polarizing member that is highly transparent and free of cracks.

The hardcoat film is as set forth above. The antireflective film may be in the form of a single-layer or multilayer film comprised of a known inorganic oxide. Examples of the inorganic oxide are silicon dioxide (SiO₂), zirconium dioxide (ZrO₂), aluminum oxide (Al₂O₃), niobium oxide (Nb₂O₅), and yttrium oxide (Y₂O₃). The forming method is not specifically limited. The thickness of the hardcoat that is formed on the polarizing film is, for example, 0.5 to 10 μm, and the thickness of the antireflective film is, for example, 0.1 to 5 μm.

In addition, functional films in the form of water-repellent films, UV-absorbing films, infrared-absorbing films, photochromic films, antistatic films, and the like can be laminated. Further examples are primers that increase adhesion between various films. Examples of primers are coatings formed by coating olefin-based, acrylic-based, epoxy-based, or urethane-based resin solutions of polyurethane resin, vinyl acetate, and ethylene vinyl copolymers.

By means of the above steps, it is possible to obtain a high-quality polarizing member in which haze caused by cracking of the polarizing film has been suppressed or reduced. Since haze is suppressed or reduced in the polarizing member obtained by the present invention, it is suited to polarizing lenses in which excellent optical characteristics are required, particularly eyeglass lenses. However, the polarizing member obtained by the present invention is not limited to a lens configuration so long as it contains the polarizing film. For example, the present invention can be applied to the manufacturing of liquid-crystal displays, light-transmitting devices, automobile and building window glass, and the like.

### EXAMPLES

The present invention will be described in greater detail below through Examples. However, the present invention is not limited to the embodiments shown in Examples.

1. Measurement of Change Over Time in the Average Molecular Weight of Epoxysilane

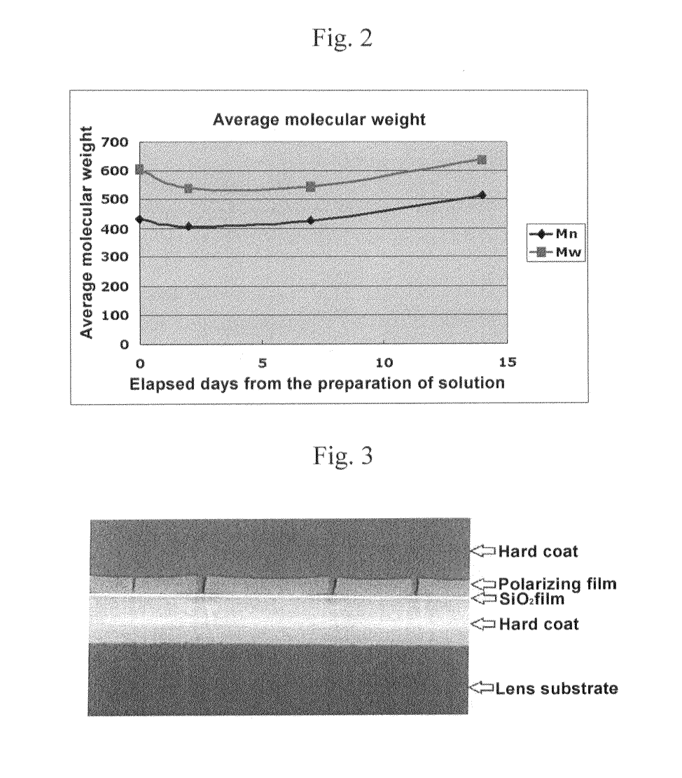

A 10 mass percent aqueous solution of γ-glycidoxytrimethoxysilane was prepared. Several milliliter quantities of samples for measuring the average molecular weight were collected on the day of, two days after, one week after, and two weeks after the preparation, and the Mw and Mn were measured. The results are given in FIG. 2. The solution was stored in air at room temperature (about 19° C.) for two weeks.

Based on the results given in FIG. 2, the following matter can be confirmed. The average molecular weight of the γ-glycidoxytrimethoxysilane in the aqueous solution decreased for two days following the preparation, reaching a minimum average molecular weight two days after the preparation. Subsequently, the average molecular weight entered a period of increase. Based on these results, the desirable time for use was determined to be within two days of the preparation.

2. Fabrication of Polarizing Lens -1

(1) Forming an Orienting Layer

A Phoenix lens (made by HOYA Corporation, refractive index 1.53, with hardcoat, diameter 70 mm, base curve 4) was employed as the lens substrate. An SiO₂ film was formed to a thickness of 0.2 μm by vacuum vapor deposition on the concave surface of the lens.

Abrasive-containing urethane foam (abrasive:, Al₂O₃ particles with an average particle diameter 0.8 μm, made by Fujimi Incorporated under the product name POLIPLA 203A; urethane foam: nearly identical in shape to the curvature of the concave surface of a spherical lens) was used to uniaxially polish the SiO₂ film that had been formed for 30 seconds at a polishing pressure of 50 g/cm³ at a rotational speed of 350 rpm. The polished lens was rinsed with pure water and dried.

(2) Forming a Polarizing Layer

After drying the lens, 2 to 3 g of a roughly 5 mass percent aqueous solution of dichroic dye (product name Varilight solution 2S made by Sterling Optics, Inc.) was spin coated onto the polished surface to form a polarizing film. In the spin coating, the aqueous solution of the dye was fed at a rotational speed of 300 rpm, this speed was held for 8 seconds, a rotational speed of 400 rpm was held for 45 seconds, and further 1,000 rpm was held for 12 seconds.

Next, a pH 3.5 aqueous solution with an iron chloride concentration of 0.15 M and a calcium hydroxide concentration of 0.2 M was prepared. The lens obtained above was immersed in this aqueous solution for about 30 seconds, withdrawn, and thoroughly rinsed in pure water. This step rendered the water-soluble dye insoluble (water-insolubilizing treatment).

(3) Processing with Aminosilane

Following (2) above, the lens was immersed in a 20 mass percent aqueous solution of γ-aminopropyltriethoxysilane for 15 minutes, rinsed three times with pure water, and thermoprocessed for 60 minutes in a heating furnace (furnace interior temperature 80° C.). It was then removed from the furnace and cooled to room temperature. Fresh γ-aminopropyltriethoxysilane solution was prepared each time processing was conducted. The change over time in the average molecular weight of the γ-aminopropyltriethoxysilane solution employed here was measured in the same manner as in 1. above at two weeks after the preparation, but no sharp change in molecular weight such as that seen in the epoxysilane measured in 1. above was observed.

(4) Processing with Epoxysilane

After cooling described above, the lens was immersed for 10 minutes in a 10 mass percent aqueous solution of γ-glycidoxypropyltrimethoxysilane in air, thermoprocessed for 60 minutes in a heating furnace (furnace interior temperature 80° C.), removed from the furnace, and cooled to room temperature. Solution that had been prepared that day, two days after, one week after, and two weeks after the preparation was employed as the 10 mass percent aqueous solution of γ-glycidoxypropyltrimethoxysilane. The solution was stored for two weeks in air at room temperature (about 19° C.).

(5) Forming a Functional Film

The lens processed in (4) above was abrasion processed with an abrasive (product name POLIPLA 103H made by Fujimi Incorporated, 0.8 μm in particle diameter) and thoroughly rinsed with water. Next, a UV-curable resin (product name 3075 made by ThreeBond Co., Ltd.) was coated by spin coating (fed at 500 rpm, held for 45 seconds). Following coating, the resin was cured at a UV irradiation level of 600 mJ/cm² with a UV-irradiating device to form a hardcoat on the lens, yielding a polarizing lens.

3. Sectional Observation of the Polarizing Lens

The sectional states of the various polarizing lenses fabricated using a 2 mass percent aqueous solution of γ-glycidoxypropyltrimethoxysilane on the day of, two days after, one week after, and two weeks after the preparation of the solution were observed by scanning electron microscope (SEM) (applied voltage: 10 kV; 5,000-fold magnification). The lenses fabricated using the solution prepared one week and two weeks after the preparation were found to exhibit cracking of the outer layer portion of the polarizing film on the hardcoat side. FIG. 3 shows a sectional photograph by SEM of a polarizing lens fabricated using a solution prepared two weeks after the preparation. By contrast, the lenses fabricated using the solution prepared on the day of and two days after the preparation did not exhibit such cracking. Measurement of the polarizing films in the SEM sectional photographs revealed a thickness of about 1.0 μm in all of the polarizing lenses.

4. Measurement of Transparency (The Haze Value)

The haze values of the polarizing lenses that had been fabricated were measured with a MH-150 haze meter made by Murakami Color Research Laboratory and the presence or absence of cloud (haze) was evaluated based on the following scale. The results are given in Table 1.

(Evaluation scale)
O: No cloud present (haze value≦0.4 percent)
X: Cloud present (haze value>0.4 percent)

TABLE 1

| Epoxysilane solution employed | Presence or absence of cloud |
|---|---|
| On the day of the preparation | ∘ |
| Two days after the preparation | ∘ |
| One week after the preparation | x |
| Two week after the preparation | x |

Based on the results given in Table 1, use of epoxysilane solution up to two days after the preparation was determined to yield high-quality polarizing lenses free of haze. Based on the fact that haze was observed in polarizing lenses in which cracks were seen in the polarizing film based on sectional observation by the SEM shown in 3. above, cracking of the polarizing film was determined to be the cause of the haze.

The above results indicate that the time of use (within two days of preparation) determined in 1. above was suitable. Accordingly, the above results indicated that determining the time of use of the epoxysilane solution based on change over time in the average molecular weight made it possible to obtain a high-quality polarizing lens free of cloud.

5. Fabrication of Polarizing Lens-2

(1) Forming an Orienting Layer through Aminosilane Treatment

The steps of forming an orienting layer through aminosilane treatment were conducted in the same manner as in 2. (1) to (3) above.

(2) Treatment with Epoxysilane

Following treatment with aminosilane, the lenses were immersed for 10 minutes in a 10 mass percent aqueous solution of γ-glycidoxypropyltrimethoxysilane in air and thermoprocessed for 60 minutes in a heating furnace (furnace interior temperature 80° C.). Subsequently, the lenses were removed from the furnace and cooled to room temperature. Necessary quantities of a solution were collected from the same solution 1 day after, 2 days after, 3 days after, 4 days after, and 8 days after the preparation of the solution, for use as the 10 mass percent aqueous solution of γ-glycidoxypropyltrimethoxysilane. The solution was stored in air at room temperature (about 19° C.) for 8 days.

(3) Forming a Functional Film

(3-1) Preparing a Hardcoat Composition

To a glass vessel equipped with magnetic stirrer were charged 17 mass parts of γ-glycidoxypropyltrimethoxysilane, 30 mass parts of methanol, and 28 mass parts of colloidal silica dispersed in water (solid component 40 mass percent, average particle diameter 15 nm). The mixture was thoroughly mixed and then stirred for 24 hours at 5° C. Next, 15 mass parts of propyleneglycol monomethyl ether, 0.05 mass part of silicone-based surfactant, and 1.5 mass parts of a curing agent in the form of aluminum acetylacetonate were added. The mixture was thoroughly stirred and filtered to prepare a hardcoat liquid (hardcoat composition).

(3-2) Forming a Hardcoat Layer

The lenses processed in (2) above were abrasion processed with an abrasive (product name POLIPLA 103H made by Fujimi Incorporated, 0.8 μm in particle diameter) and thoroughly rinsed with water. Next, the hardcoating composition prepared in (3-1) above was coated by spin coating and heat cured for 60 minutes at 100° C. to form a hardcoat layer about 3 μm in thickness.

6. Measurement of Transparency (The Haze Value)

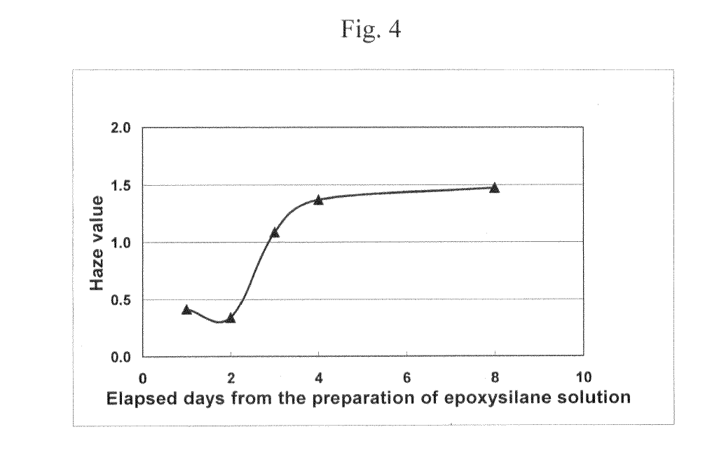

The haze value of each of the polarizing lenses fabricated in 5. above was measured with a MH-150 haze meter made by Murakami Color Research Laboratory. The results are given in FIG. 4.

As shown in FIG. 4, when the epoxysilane solution that exceeded the time of use determined in 1. above (within two days of preparation), the haze value increased sharply (cloud was generated). These results indicated that determining the time of use of the epoxysilane solution based on change over time in the average molecular weight made it possible to obtain a high-quality polarizing lens free of cloud.

The present invention is useful in the field of manufacturing polarizing lenses such as eyeglass lenses.

What is claimed is:

1. A method of manufacturing a polarizing member comprising:
forming a polarizing film by coating a dichroic dye-containing solution on an orienting layer,
preparing an epoxy group-containing silane coupling agent solution by adding an epoxy group-containing silane coupling agent to an aqueous solvent,
coating the epoxy group-containing silane coupling agent solution thus prepared on the polarizing film and then conducting thermoprocessing, and
determining the time elapsing between the preparation of the epoxy group-containing silane coupling agent solution and the coating thereof based on change in an average molecular weight of the silane coupling agent in the epoxy group-containing silane coupling agent solution.

2. The method of manufacturing a polarizing member according to claim 1, wherein
the epoxy group-containing silane coupling agent solution has a property in that the average molecular weight undergoes a temporary drop, after which it begins to increase, and
the time elapsing between the preparation and the coating is set within a period from when the solution is prepared to when a given period is elapsed following the start of the increase in the average molecular weight.

3. The method of manufacturing a polarizing member according to claim 1, further comprising forming a functional film on the polarizing film that has been subjected to the thermoprocessing.

4. The method of manufacturing a polarizing member according to claim 1, comprising, prior to coating the epoxy group-containing silane coupling agent solution, coating an amino group-containing silane coupling agent solution on the polarizing film and then conducting thermoprocessing.

5. The method of manufacturing a polarizing member according to claim 1, wherein the dichroic dye is water-soluble, and the method comprises subjecting the polarizing film formed to water-insolubilizing treatment of the dichroic dye.

6. The method of manufacturing a polarizing member according to claim 1, wherein the orienting layer comprises an oxide of silicon.

7. The method of manufacturing a polarizing member according to claim 1, wherein the polarizing member is a polarizing lens.
